(19) United States
(12) Patent Application Publication
(10) Pub. No.: US 2017/0004901 A1
(43) Pub. Date: Jan. 5, 2017

(54) FIXED-ARRAY ANISOTROPIC CONDUCTIVE FILM USING CONDUCTIVE PARTICLES WITH BLOCK COPOLYMER COATING

(71) Applicants: Rong-Chang Liang, Cupertino, CA (US); Yuhao Sun, Fremont, CA (US); Zhiyao An, Los Altos, CA (US)

(72) Inventors: Rong-Chang Liang, Cupertino, CA (US); Yuhao Sun, Fremont, CA (US); Zhiyao An, Los Altos, CA (US)

(73) Assignee: Trillion Science, Inc., Fremont, CA (US)

(21) Appl. No.: 15/211,042

(22) Filed: Jul. 15, 2016

Related U.S. Application Data
(62) Division of application No. 14/022,791, filed on Sep. 10, 2013, now abandoned.

(51) Int. Cl. H01B 3/44; H05K 1/02; H01B 3/28; H01L 23/00; H01B 3/30

(52) U.S. Cl. CPC H01B 3/447; H01L 24/83; H01L 24/29; H01B 3/307; H01B 3/442; H01B 3/28; H05K 1/0213; H01L 2224/83851; H01L 2224/29444; H01L 2224/29469; H01L 2224/29439; H01L 2224/29447; H01L 2224/2946; H01L 2224/29455; H01L 2224/29411; H01L 2224/29424; H01L 2224/29423

(57) ABSTRACT

Structures and manufacturing processes of an ACF array and more particularly a non-random particles are transferred to the array of microcavities of predetermined configuration, shape and dimension. The manufacturing process includes fluidic filling of conductive particles surface-treated with a block copolymer composition onto a substrate or carrier web comprising a predetermined array of microcavities. The thus prepared filled conductive microcavity array is then over-coated or laminated with an adhesive film.

### CROSS REFERENCE TO RELATED APPLICATION

This application is a divisional of U.S. application Ser. No. 14/022,791, filed Sep. 10, 2013, which is incorporated herein by reference in its entirety.

### BACKGROUND

### 1. Field

This invention relates generally to structures and manufacturing methods for anisotropic conductive films (ACF). More particularly, this invention relates to structures and manufacturing processes for an ACF having improved resolution and reliability of electrical connections in which the conductive particles are treated with a composition comprising a two-phase block copolymer type of elastomer comprising a segment that is incompatible with the ACF adhesive.

### 2. Description of the Related Art

Anisotropic Conductive Film (ACF) is commonly used in flat panel display driver integrated circuit (IC) bonding. A typical ACF bonding process comprises for example, a first step in which the ACF is attached onto the electrodes of the panel glass; a second step in which the driver IC bonding pads are aligned with the panel electrodes; and a third step in which pressure and heat are applied to the bonding pads to melt and cure the ACF within seconds. The conductive particles of the ACF provide anisotropic electrical conductivity between the panel electrodes and the driver IC. Lately, ACF has also been used widely in applications such as flip chip bonding and photovoltaic module assembly.

The conductive particles of a traditional ACF are typically randomly dispersed in the ACF. There is a limitation on the particle density of such a dispersion system due to X-Y conductivity. In a fine pitch bonding application, the conductive particle density must be high enough to have an adequate number of conductive particles bonded on each bonding pad. However, the probability of a short circuit or undesirable high-conductivity in the insulating area between two bonding pads also increases due to the high density of the conductive particles and the characteristics of random dispersion.

Recently, the demand for display devices of high resolution and/or degree of integration has increased dramatically. For example, the typical minimum bonding area required for a chip-on-glass (COG) device has decreased from 1200-1600 μm² to 400-800 μm². It has been disclosed in U.S. Patent Application Publication 2012/0295098 FIXED-ARRAY CONDUCTIVE FILM USING SURFACE MODIFIED CONDUCTIVE PARTICLES, that the use of coupling agent-treated conductive particles in the fixed array ACF resulted in significant improvement in the dispersion stability of conductive particles between the electrode gap areas and reduced the risk of particle aggregation and the probability of a short circuit therein. To further reduce the bonding area, for example, to below 400 um² and yet provide a satisfactory connection conductivity in the Z-direction, a concentration of conductive particles as high as 50,000 pcs/mm² before bonding may be necessary even for fixed array ACFs of a high particle capture rate. Assuming a particle size of 3.0 um, a particle density of 50,000 pcs/mm² before bonding , a particle capture rate of 30-50% in the electrode area, a bonding area of 400 um² and a gap area of 1000 um², the particle concentration in the gap area could be as high as 60,000 to 64,000 pcs/mm² or a total particle cross-section area of 85 -90% of the gap area. For a gap area of 600 um², the particle concentration in the gap area after bonding will increase to about 66,667-73,333 pcs/mm² or the total particle cross-section area increase to 94.2-103.6% of the gap area. In all cases, the particle density in the gap area is well above the maximum packaging density of the particles having a narrow particle size distribution and most of the particles will stack up in the gap area and aggregation or cluster of particles appears to be un-avoidable. The particle density in the gap area will be even higher for traditional non-fixed array ACFs because of their significantly lower particle capture rate on the electrodes/bumps.

To enable ultra-fine pitch chip bonding/connections, it's highly desirable to have conductive particles having a high insulation resistance even in their aggregate state in the gap area, and a very low contact resistance in the connected electrodes after bonding by a mild bonding pressure/temperature.

ACFs prepared with conductive particles pre-coated with a solvent soluble or dispersible polymeric insulating layer have been disclosed in the following references: Japan Kokai 10-134634 (1998) to Y. Marukami;. 62-40183 (1987), to Choi I I Ind; and U.S. Pat. No. 5,162,087 (1992) to Soken Chemical & Engineering Co. The insulating coating on the conductive particles reduces the risk of a short between adjacent electrodes caused by particle aggregation in the electrode gaps or spacing areas. However, a solvent soluble or dispersible insulating layer tends to desorb or dissolve into the adhesive layer during storage or even during the fluid preparation or coating of the ACFs.

The use of crosslinked or gelled polymer layer/particles and inorganic particulates on the surface of the conductive particles in an ACF to reduce the risk of desorbing or dissolution of the insulating layer/particles and improve the ACF bonding performance for fine-pitch applications has been disclosed in the following references: U.S. Pat. No. 5,965,064; U.S. Pat. No. 6,632,532; U.S. Pat. No. 7,846,547; U.S. Pat. No. 8,309,224 to Sony Chemicals Corp.; U.S. Published Applications 2010/0327237; 2012/0097902; US 2012/0104333 to Hitachi Chemical Co.; U.S. Pat. No. 7,252,883; U.S. Pat. No. 7,291,393 to Sekisui Chemical Co.; U.S. Pat. No. 7,566,494; U.S. Pat. No. 7,815,999; U.S. Pat. No. 7,851,063; U.S. Pat. No. 8,129,023 to Cheil Industries, Inc.; U.S. Published Application 2006/0263581 to J G Park, J B Jun, T S Bae and J H Lee. However, in most cases, the crosslinked or gelled insulating layer or particulates on the conductive particles resulted in a trade off in the bonding temperature and/or pressure required to reach the desirable connection conductivity in the Z-direction. In some cases, true ohm contact of the connected electrodes may not be achieveable if the insulating layer can not be removed to expose the conductive (metallic) surface of the particles during the bonding process. Moreover, the crosslinked or gelled protection materials, after depleted from the surface of the conductive particles, often become redundant or even harmful additives that are incompatible with the adhesive and often degrade the ACF performances.

U.S. Published Application 2010/0101700 to Liang et al. (“Liang”) discloses conductive particles are arranged in pre-determined array patterns in fixed-array ACF (FACF). In one embodiment, a microcavity array may be formed directly on a carrier web or on a cavity-forming layer pre-coated on the carrier web and the distance between the particles are predefined and well-controlled for example, by a laser ablation process, by an embossing process, by a stamping process, or by a lithographic process. Such a non-random array of conductive particles is capable of ultra fine pitch bonding without the likelihood of short circuit. It provides a significantly higher particle capture rate on the electrodes or bump pads and results in a much less particle concentration in the gap area than the traditional ACFs. Moreover, it also provides a significant improvement in the uniformity of contact resistance or impedance since the number of particles on each bonding pad is precisely controlled. In one embodiment, the particles may be partially embedded in the adhesive film forming the ACF. The uniformity of contact resistance or impedance is becoming very critical in the advanced high resolution video rate flat panels, particularly current driven devices such as OLED, and the fixed-array ACF clearly demonstrated its advantages in such applications.

### SUMMARY OF THE DISCLOSURE

This disclosure improves the fixed-array ACF of Liang by providing an ACF in which the conductive particles are treated or coated with a composition comprising a two phase block copolymer having at least a segment or block that is incompatible with the ACF adhesive as determined by a comparison of the solubility parameter of the incompatible block with that of the ACF adhesive. In one embodiment, the conductive particles can be partially embedded in the adhesive resin such that at least a portion of the surface is not covered by the adhesive. In one embodiment, the particles are embedded to a depth of about one-third to three-fourths their diameter. In one particular non-limiting embodiment, the conductive particles are coated with a block copolymer that includes a hard (high Tg or Tm) block or segment that is not compatible with the adhesive resin (e.g., an epoxy, cyanate ester or an acrylic resin) and, more particularly is essentially insoluble in multifunctional epoxides, acrylates, methacrylates or cyanate esters.

In still one of the embodiments, in addition to the incompatible block, the thermoplastic block copolymer further comprises a soft block or segment (low Tg or Tm) that is compatible or partially compatible with the adhesive resin.

It has been found that block copolymers, particularly those comprising a block that is incompatible with the adhesive composition, provided superior insulation properties for conductive particles even at their aggregated states and yet can be easily removed at mild bonding temperature/pressure conditions (for example, 80 to 200° C. and ≦3 MPa) to form true ohm contact between the conductive particles and the electrodes in the connection area. Block copolymers are also readily soluble or dispersible in common solvents and encapsulation of the conductive particles may be achieved efficiently by, for example, addition of non-solvents/additives or change of temperature to form a protective thermoplastic elastomer layer or particulates on the surface of conductive particles. Also, the ACFs comprising conductive particles encapsulated with the block copolymer showed significantly lower minimum bonding space and significant improvements in the adhesive properties including the thermal shock and HHHT (high temperature, high humidity) environmental stability. In some cases, the use of such insulated conductive particles also reduces the microvoid content and improves reliability and fatigue resistance. Not to be bound by theory, the block copolymer may function as an impact modifier or low profile additive in the adhesive matrix. The incompatibility between the block copolymer incompatible segment and the adhesive composition reduces the likelihood of desorption of the encapsulation layer from the conductive particles during processing and storage. And, the thermoplastic characteristics improved the removal of the encapsulation layer during the bonding process and allow true ohm contact between the particles and the electrodes even at mild bonding conditions.

Conventionally, the conductive particles used in ACFs are coated with a layer of insulative polymer to reduce the tendency for the particle surfaces to touch and cause an electrical short to occur in the X-Y plane. However, this insulative layer complicates the assembly of the ACF because, in order to achieve Z-direction conductivity, the insulative layer on the surface of the conductive particle must be displaced. This increases the temperature or amount of pressure that must be applied to the ACF (for example from a pressure bar) to achieve electrical contact between the glass (Chip-on-Glass, COG) or film (Chip-on-Film, COF) substrate and the chip device, particularly when a thermoset insulating layer is used to protect the conductive particles. In accordance with one embodiment, by treating the conductive particle with a block copolymer, the incidence of short circuits can be reduced. At the same time, the block copolymer significantly improves the dispersibility of the particles in the adhesive filled in the non-contact area or the spacing among electrodes and reduces the probability of particle aggregation therein. Consequently, the probability of short circuits in the X-Y plane can be reduced. Moreover. the block copolymer is much easier to remove from the particle surface than a thermoset insulation layer to assure a true ohm contact in the connected electrodes.

### BRIEF DESCRIPTION OF THE DRAWING

The FIGURE is a laboratory scale device for coating conductive particles with a thermoplastic elastomer.

### DETAILED DESCRIPTION

U.S. Published Applications 2010/0101700 2012/0295098 and 2013/0071636 to Liang et al. are incorporated herein in their entirety by reference.

Any of the conductive particles previously taught for use in ACFs may be used in practicing this disclosure. Gold coated particles are used in one embodiment. In one embodiment, the conductive particles have a narrow particle size distribution with a standard deviation of less than 10%, preferably less than 5%, even more preferably less than 3%. The particle size is preferably in the range of about 1 to 250 μm more preferably about 2-50 μm even more preferably about 3-10 μm. In another embodiment the conductive particles have a bimodal or a multimodal distribution. In another embodiment, the conductive particles have a so called spiky surface. The size of the microcavities and the conductive particles are selected so that each microcavity has a limited space to contain only one conductive particle. To facilitate particle filling and transferring, a microcavity having a tilted wall with a wider top opening than the bottom may be employed.

In one embodiment, conductive particles including a polymeric core and a metallic shell are used. Useful polymeric cores include but are not limited to, polystyrene, polyacrylates, polymethacrylates, polyvinyls, epoxy resins, polyurethanes, polyamides, phenolics, polydienes, polyolefins, aminoplastics such as melamine formaldehyde, urea formaldehyde, benzoguanamine formaldehyde and their oligomers, copolymers, blends or composites. If a composite material is used as the core, nanoparticles or nanotubes of carbon, silica, alumina, BN, TiO₂ and clay are preferred as the filler in the core. Suitable materials for the metallic shell include, but are not limited to, Au, Pt, Ag, Cu, Fe, Ni, Sn, Al, Mg and their alloys. Conductive particles having interpenetrating metal shells such as Ni/Au, Ag/Au, Ni/Ag/Au are useful for hardness, conductivity and corrosion resistance. Particles having rigid spikes such as Ni, carbon, graphite are useful in improving the reliability in connecting electrodes susceptible to corrosion by penetrating into the corrosive film if present. Such particles are available from Sekisui KK (Japan) under the trade name MICROPEARL, Nippon Chemical Industrial Co., (Japan) under the trade name BRIGHT, and Dyno A.S. (Norway) under the trade name DYNOSPHERES. The spike might be formed by doping or depositing small foreign particles such as silica on the latex particles before the step of electroless plating of Ni followed by partial replacement of the Ni layer by Au.

In one embodiment, narrowly dispersed polymer particles may be prepared by, for example, seed emulsion polymerization as taught in U.S. Pat. Nos. 4,247,234, 4,877,761, 5,216,065 and the Ugelstad swollen particle process as described in Adv., Colloid Interface Sci., 13, 101 (1980); J. Polym. Sci., 72, 225 (1985) and “Future Directions in Polymer Colloids”, ed. El-Aasser and Fitch, p. 355 (1987), Martinus Nijhoff Publisher. In one embodiment, monodispersed polystyrene latex particle of about 5 μm diameter is used as a deformable elastic core. The particle is first treated in methanol under mild agitation to remove excess surfactant and to create microporous surfaces on the polystyrene latex particles. The thus treated particles are then activated in a solution comprising PdCl₂, HCl and SnCl₂ followed by washing and filtration with water to remove the Sn⁴⁺ and then immersed in an electroless Ni plating solution (from for example, Surface Technology Inc, Trenton, N.J.) comprising a Ni complex and hydrophosphite at 90° C. for about 30 to about 50 minutes. The thickness of the Ni plating is controlled by the plating solution concentration and the plating temperature and time. In one embodiment, the conductive particles are formed with spikes. These spikes may be formed as, without limitation, sharpened spikes or nodular.

In accordance with one embodiment, the conductive particles are treated/coated with a thermoplastic block copolymer preferably a two-phase thermoplastic elastomer (TPE). Essentially, a hard thermoplastic phase is coupled mechanically or chemically with a soft elastomer phase, resulting in a block copolymer that has the combined properties of the two phases. Thorough reviews of thermoplastic elastomer block copolymers may be found in J. G. Drobny, Handbook of Thermoplastic Elastomers (2007); A. Calhoun, G.Holden and H. Krichedorf, Thermoplastic Eladtomers (2004); G. Wolf, Thermoplastic Elastomers, (2004); and P. Rader Handbook of Thermoplastic Elastomers (1988).

Useful block copolymers for the encapsulation of conductive particles in various embodiments of this invention include, but are not limited to, ABA, AB, (AB)n and ABC block copolymers such as styrenic block copolymers including SBS (styrene-butadiene-styrene block copolymers), SIS (styrene-isoprene-styrene), polystyrene, poly-α-methyl styrene, polybutadiene, polyisoprene, polyurethane, polysiloxane block copolymers, polyester block copolymers, polyamide block copolymers, polyolefin block copolymers, etc.

Particularly useful copolymers are those block copolymers comprising a block that is incompatible with the ACF adhesive resin. Among the thermoset adhesives typically used in ACFs, epoxy based and acrylic based adhesives including epoxy or acrylic resins are particularly useful. Representative examples of polymer blocks that are incompatible with epoxy resin based adhesives include polystryene, poly-α-methyl styrene, polybutadiene, polyisoprene, polydimethysiloxane, poly(alkyl acrylate) and poly(alkyl methacrylate), particularly those with an alkyl group having more than 2 carbon atoms, polyolefin, polycyclic olefin . . . etc. The incompatible segment of a block copolymer used with an ACF epoxy adhesive typically has a solubility parameter of less than about 9.2 or higher than about 11.5. Representative examples of polymer blocks that are incompatible with acrylic resin based ACF adhesives include polystyrene, poly-α-methyl styrene, polybutadiene, polyisoprene, polydimethysiloxane, polyolefin, polycyclic olefin, etc. The incompatible segment of a block copolymer used with an acrylic ACF adhesive typically has a solubility parameter of less than about 9.0 or higher than about 11.5. In still another embodiment, the incompatible segment of a block copolymer used with an acrylic ACF adhesive preferably has a solubility parameter of less than about 9.0 and is not capable of forming a strong interaction such as acid-base and hydrogen bonding with the adhesive polymers.

In one embodiment of the invention, the incompatible block is present in the block copolymer in an amount of about 5 to 95% by weight based on the total weight of the elastomer and, more particularly, the incompatible polymer block is present in an amount of about 20 to 80% by weight based on the total weight of the elastomer. In one preferred embodiment, the thermoplastic block copolymer is a thermoplastic elastomer. In one embodiment, the soft block or segment has a Tg or Tm lower than about 25° C. (preferably lower than 0° C.), and in one embodiment, the hard block or segment has a Tg or Tm higher than about 50° C. (preferably higher than 90° C.). The incompatible block or segment of the block copolymer has a difference in solubility parameter of at least about 1.2 (Cal/cc)^{1/2} compared to the ACF adhesive resin.

The block copolymer may be used alone as the insulation layer for the conductive particles. Alternatively, a blend of a block copolymer with a thermoplastic polymer (TPP) that is miscible with the hard or soft blocks of the block copolymer may be used for improved encapsulation and handle-ability. Preferably the TPP additive used is compatible with the hard block copolymer block that is incompatible with the ACF adhesive. In one embodiment of the invention, the thermoplastic polymer additive is a homopolymer of one of the hard or soft blocks. In still another embodiment of the invention, the block copolymer is a styrenic block copolymer and the TPP additive is polystyrene. The block copolymer and the TPP are blended in a ratio of block copolymer:TPP of about 20:80 to 95:5 by weight, preferably about 30:70 to 70:30 by weight in one embodiment. In one embodiment the TPP exhibits a solubility difference with respect to the ACF adhesive of a least about 1.2 (Cal/cc)^{1/2}.

In one embodiment, the insulation layer comprising the block copolymer is applied to the conductive particles to achieve a protective layer having an average thickness of 0.03-0.5 um, more preferably 0.05-0.2 um. In another embodiment, the volume ratio of the insulation layer to the conductive particle is about from about 0.2/10 to 3/10, more preferably from about 0.5/10 to 2/10. In still another embodiment, the insulation layer is a blend of a styrenic block copolymer with a polystyrene having about 20 to 80% by weight of polystyrene, more preferably 40-60% by weight of polystyrene.

The amount of the insulation layer may be optimized depending on the minimum bonding space and the minimum bonding area required. A lower minimum bonding space may be achieved by a higher coverage of the insulation layer but with the tradeoff in the contact conductivity in the bonding area. The Tg or heat distortion temperature of the insulation layer may be adjusted by the ratio of the soft and blocks of the block copolymer or by the concentration of additive thermoplastic polymer.

In one embodiment of the invention, the thermoplastic elastomer is present on the surface of the conductive particle in an amount of about 5 to 100% surface coverage, more preferably 20 to 100% of coverage.

A fixed array ACF may be prepared by fluidic distribution of conductive particles on a microcavity array followed by a transfer process to transfer the particles to an adhesive layer as taught in U.S. Published Applications 2010/0101700, 2012/0295098 and 2013/0071636 to Liang et al. which are incorporated herein by reference. A microcavity array may be formed directly on a carrier web or on a cavity-forming layer pre-coated on the carrier web. Suitable materials for the web include, but are not limited to polyesters such as polyethylene terephthalate (PET) and polyethylene naphthalate (PEN), polycarbonate, polyamides, polyacrylates, polysulfone, polyethers, polyimides, and liquid crystalline polymers and their blends, composites, laminates or sandwich films. A suitable material for the cavity-forming layer can include, without limitation, a thermoplastic material, a thermoset material or its precursor, a positive or a negative photoresist, or an inorganic material. To achieve a high yield of particle transfer, the carrier web may be preferably treated with a thin layer of release material to reduce the adhesion between the microcavity carrier web and the adhesive layer. The release layer may be applied by coating, printing, spraying, vapor deposition, thermal transfer, or plasma polymerization/crosslinking either before or after the microcavity-forming step. Suitable materials for the release layer include, but are not limited to, fluoropolymers or oligomers, silicone oil, fluorosilicones, polyolefines, waxes, poly(ethyleneoxide), poly(propyleneoxide), surfactants with a long-chain hydrophobic block or branch, or their copolymers or blends.

The microcavities may be formed directly on a plastic web substrate with, or without, an additional cavity-forming layer. Alternatively, the microcavities may also be formed without an embossing mold, for example, by laser ablation or by a lithographic process using a photoresist, followed by development, and optionally, an etching or electroforming step. Suitable materials for the cavity forming layer can include, without limitation, a thermoplastic, a thermoset or its precursor, a positive or a negative photoresist, or an inorganic or a metallic material. As to laser ablating, one embodiment generates a deep UV laser beam for ablation having power in the range of between about 0.1 W/cm² to about 200 W/² employing a pulsing frequency being between about 0.1 Hz to about 500 Hz; and applying between about 1 pulse to about 100 pulses. In a preferred embodiment, laser ablation power is in the range of between about 1 W/cm² to about 100 W/cm2, employing a pulsing frequency of between about 1 Hz to about 100 Hz, and using between about 10 pulses to about 50 pulses. It also is desirable to apply a carrier gas with vacuum, to remove debris.

To enhance transfer efficiency, the diameter of the conductive particles and the diameter of the cavities have specific tolerance. To achieve a high transfer rate, the diameter of the cavities should have specific tolerance less than about 5% to about 10% standard deviation requirement based on the rationales set forth in U.S. Patent Publication 2010/0101700.

In a further embodiment, the non-random ACF microarray can be provided in a unimodal implementation, in a bimodal implementation, or in a multimodal implementation. In an embodiment of a unimodal particle implementation, particles in a non-random ACF microcavity array can have a particle size range distributed about a single mean particle size value, typically between about 2 μm to about 6 μm with embodiments featuring a narrow distribution including a narrow particle size distribution having a standard deviation of less than about 10% from the mean particle size. In other embodiments featuring a narrow distribution, a narrow particle size distribution may be preferred to have a standard deviation of less than about 5% from the mean particle size. Typically, a cavity of a selected cavity size is formed to accommodate a particle having a selected particle size that is approximately the same as the selected cavity size.

Thus, in a unimodal cavity implementation, microcavities in a non-random ACF microcavity array can have a cavity size range distributed about a single mean cavity size value, typically between about 2 μm to about 6 μm with embodiments featuring a narrow distribution including a narrow cavity size distribution having a standard deviation of less than 10% from the mean cavity size. In other embodiments featuring a narrow distribution, a narrow cavity size distribution may be preferred to have a standard deviation of less than 5% from the mean cavity size.

In a bimodal particle implementation of a non-random ACF microcavity array, ACF particles can have two ACF particle size ranges, with each ACF particle type having a corresponding mean ACF particle size value, with a first mean ACF particle size being different from a second mean ACF particle size. Typically, each mean ACF particle size can be between about 2 μm to about 6 μm. In some embodiments of a bimodal particle implementation, each mode corresponding to respective mean ACF particle size values may have a corresponding narrow particle size distribution. In some selected embodiments, a narrow particle size distribution can be characterized by having a standard deviation of less than 10% from the mean particle size. In other selected embodiments, a narrow particle size distribution can be characterized by having a standard deviation of less than 5% from the mean particle size.

In an embodiment of a fabrication process for a multimodal non-random ACF microcavity array, particles may be selected to provide a first ACF particle type having a first mean ACF particle size with a first ACF particle distribution, a second ACF particle type having a second mean ACF particle size with a second ACF particle distribution, and a third ACF particle type having a third mean ACF particle size with a third ACF particle distribution. In this example, the second ACF particle type has a larger mean ACF particle size than the first ACF particle type, and the third ACF particle type has a larger mean ACF particle size than the second ACF particle type. To manufacture such multimodal non-random ACF array, a multimodal microcavity array may be formed by selectively forming on an ACF microcavity array substrate to receive the aforementioned three ACF particle types, a first cavity type having a first mean ACF cavity size, a second cavity type having a second mean ACF cavity size, and a third cavity type having a third mean ACF cavity size. One method of manufacture can include applying the larger, third-type ACF particles to the microcavity array, followed by applying the intermediate, second-type ACF particles to the microcavity array, followed by applying the smaller, first-type ACF particles to the multimodal ACF microcavity array. The ACF particles may be applied using one or more of the aforementioned array-forming techniques.

In a specific embodiment, the invention further discloses a method for fabricating an electric device. The method includes a step of placing a plurality of electrically conductive particles that include a core material and an electrically conductive shell surface-treated with a coupling agent or insulation material into an array of microcavities followed by overcoating or laminating an adhesive layer onto the filled microcavities. In a one embodiment, the step of placing a plurality of surface treated conductive particles into an array of microcavities comprises a step of employing a fluidic particle distribution process to entrap each of the conductive particles into a single microcavity. The depth of the microcavity is important in the processes of filling and of transferring conductive particles and partially embedding the conductive particles in the adhesive layer. With a deep cavity (relative to the size of the conductive particles), it's easier to keep the particle in the cavity before transfer to the epoxy layer; however, it's more difficult to transfer the particles. With a shallow cavity, it's easier to transfer the particle to the adhesive layer; however, it's more difficult to keep the particles that are filled in the cavity before the transfer of the particles.

In one embodiment, particle deposition may be effected by applying a fluidic particle distribution and entrapping process, in which each conductive particle is entrapped in one microcavity. A number of entrapping processes can be used. For example, in one embodiment disclosed in the Liang Publication, a novel roll-to-roll continuous fluidic particle distribution process can be used to entrap only one conductive particle into each microcavity. The entrapped particles then can be transferred from the microcavity array to predefined locations on an adhesive layer. Typically, the distance between these transferred conductive particles must be greater than the percolation threshold, which is the density threshold at which the conductive particles aggregate. In general, the percolation threshold corresponds to the structure of the microcavity array structure and to the plurality of conductive particles.

A non-random ACF array that may include more than one set of microcavities either on the same or opposite side of the adhesive layer, with the microcavities typically having predetermined size and shape. In one particular embodiment, the microcavities on the same side of the adhesive film have substantially same height in the Z-direction (the thickness direction). In another embodiment, the microcavities on the same side of the adhesive film have substantially same size and shape. The ACF may have more than one set of microcavities even on the same side of the adhesive. In one embodiment, a microcavity array containing microcavities of about 6 μm (diameter) by about 4 μm (depth) by about 3 μm (partition) may be prepared by laser ablation on an approximately 3 mil heat-stabilized polyimide film (PI, from Du Pont) to form the microcavity carrier. An exemplary procedure for particle filling in accordance with one embodiment is as follows: the PI microcavity array web is coated with a conductive particle dispersion using a smooth rod. The procedure may be repeated to assure that there are no unfilled microcavities. The filled microcavity array is allowed to dry at about room temperature for about 1 minute and the excess particles are wiped off gently by for example a rubber wiper or a soft lint-free cloth soaked with acetone solvent. Microscope images of the filled microcavity array may be analyzed by ImageTool 3.0 software. A filling yield of more than about 99% was observed for almost all the microcavity arrays evaluated. The particle density may be varied by using different design of microcavity array. Alternatively, the particle density may be adjusted conveniently by changing the degree of filling through either the concentration of the conductive particle dispersion or by the number of passes in the filling process.

Two exemplary step-by-step procedures for particle filling and transfer are as follows:

Nickel particles: Adopting the particle filling procedure described in the above example, a polyimide microcavity sheet with a 6×2×4 μm array configuration was filled with about 4 μm Umicore Ni particles. The attained percentage of particle filling was typically greater than about 99%. An epoxy film was prepared with about 15 μm target thickness. The microcavity sheet and the epoxy film were affixed, face to face, on a steel plate. The steel plate was pushed through a HRL 4200 Dry-Film Roll Laminator, commercially available from Think & Tinker. The lamination pressure was set at a pressure of about 6 lb/in (about 0.423 g/cm2) and a lamination speed of about 2.5 cm/min. Particles were transferred from PI microcavity to epoxy film with an efficiency greater than about 98%. Acceptable tackiness during prebond at about 70. degree. C. and conductivity after main bond at about 170° C. was observed after the resultant ACF film was bonded between two electrodes using a Cherusal bonder (Model TM-101P-MKIII.)

Gold particles: Similarly, a polyimide microcavity sheet with an approximately 6×2×4 μm array configuration was filled with monodispersed 3.2 μm Au—Ni overcoated latex particles. The attained percentage of particle filling was also greater than about 99%. An epoxy film was prepared using a #32 wire bar with a targeted thickness of about 20 μm. Both were placed on a steel plate face-to-face. The microcavity sheet and the epoxy film were affixed, face to face, on a steel plate. The steel plate was pushed through a HRL 4200 Dry-Film Roll Laminator, commercially available from Think & Tinker. The lamination pressure was set at a pressure of about 6 lb/in (or about 0.423 g/cm2) and a lamination speed of about 2.5 cm/min. An excellent particle transfer efficiency (greater than about 98%) was observed. The resultant ACF films showed acceptable tackiness and conductivity after bonded between two electrodes by the Cherusal bonder (Model TM-101P-MKIII.)

In one embodiment, microcavity loop is placed onto a particle filling coater with cantilever rollers. A 3 to 6 wt % dispersion of conductive particles in isopropyl alcohol (IPA) was mixed by mechanical stirring and dispensed by a fluidic process via for examples a slot or slit coating die, a curtain, or a spraying nozzle through a L/S 13 tubing with a Masterflex pump available from Cole Parmer. Conductive particles were filled into microcavities using a knitted 100% polyester wiper wrapped roller. Excess particles (outside of the microcavity) were carefully removed using a polyurethane roller from Shima American Co., with a vacuum device to recycle conductive particles. The recovered particles may be collected and recirculated to the supply hopper for reapplication to the web. In one embodiment, more than one dispensing station may be employed to ensure that a conductive particle is entrapped in each microcavity and thereby minimize or reduce the number of microcavities not containing particles.

The entrapped particles then can be transferred from the microcavity array to predefined locations on an adhesive layer. Typically, the distance between these transferred conductive particles must be greater than the percolation threshold, which is the density threshold at which the conductive particles become connected or aggregate. In general, the percolation threshold is a function of the structure/pattern of the microcavity array structure and to the plurality of conductive particles.

It can be desirable to employ one or more processes to remove excess conductive particles, for example, after fluidic assembly. Roll-to-roll continuous fluidic particle distribution processes may include a cleaning process to remove excess conductive particles from the surface of microcavity array. A cleaning process may be a non-contact cleaning process, a contact cleaning process, or an effective combination of non-contact and contact cleaning processes.

Certain exemplary embodiments of the particle cleaning process, employ a non-contact cleaning process, including, without limitation, one or more of a suction process, an air blow process, or a solvent spray process. Removed excess conductive particles can be accumulated, for example, by a suction device for recycle or reuse. The non-contact suction process can further be assisted by dispensing a cleaning fluid such as, without limitation, by spraying a solvent or a solvent mixture, to improve the cleaning efficiency. Certain other exemplary embodiments of the present invention may employ a contact cleaning process to remove the excess conductive particles from the surface of the microcavity array. The contact cleaning process includes the use of a seamless felt, a wiper, a doctor blade, an adhesive material, or a tacky roll. When a seamless felt is applied, a suction process also may be used to recycle conductive particles from the seamless felt surface and to refresh the felt surface. In this felt/suction process, both capillary force and suction force draw the excess conductive particles with suction force applied from inside of seamless felt to remove and recycle the excess particles. This suction process can be further assisted by dispensing a cleaning fluid, a solvent, or a solvent mixture to improve the cleaning efficiency.

After the fluidic filling step, the conductive particles in the microcavities may be transferred to the substrate, which is pre-coated with an uncured adhesive or which is coated on the process line. The microcavity belt is reused by repeating the particle filling and transferring steps.

The adhesives used in the ACF may be thermoplastic, thermoset, or their precursors. Useful adhesives include but are not limited to pressure sensitive adhesives, hot melt adhesives, heat or radiation curable adhesives. The adhesives may comprise for examples, epoxide, phenoxy resin, phenolic resin, amine-formaldehyde resin, polybenzoxazine, polyurethane, cyanate esters, acrylics, acrylates, methacrylates, vinyl polymers, rubbers such as poly (styrene-co-butadiene) and their block copolymers, polyolefins, polyesters, unsaturated polyesters, vinyl esters, polycaprolactone, polyethers, silicone resins and polyamides. Epoxide, cyanate esters and multifunctional acrylates are particularly useful. Catalysts or curing agents including latent curing agents may be used to control the curing kinetics of the adhesive. Useful curing agents for epoxy resins include, but are not limited to, dicyanodiamide (DICY), adipic dihydrazide, 2-methylimidazole and its encapsulated products such as Novacure HX dispersions in liquid bisphenol A epoxy from Asahi Chemical Industry, amines such as ethylene diamine, diethylene triamine, triethylene tetraamine, BF3 amine adduct, Amicure from Ajinomoto Co., Inc, sulfonium salts such as diaminodiphenylsulphone, p-hydroxyphenyl benzyl methyl sulphonium hexafluoroantimonate.

The invention is illustrated in more detail by the following non-limiting examples.

Preparation of Fixed Array ACF

An epoxy adhesive composition consisting of 5.0 parts of glycerol triglycidyl ether from Aldrich, 6.0 parts of bisphenol F type epoxy resin JER YL983U from Japan Epoxy Resins, Tokyo; 29.66 parts of PKFE from InChem Phenoxy Resin, SC; 4.24 parts of M52N from Arkema Inc., PA; 2.8 parts of Epalloy 8330 from CVC Thermoset Specialties, NJ; 2.8 parts of Paraloid™ EXL-2335 from Dow Chemicals, TX; 1.0 part of Ti-Pure R706 from Du Pont, DE; 48.0 parts of Novacure HXA 3922 from Asahi Chemicals, Tokyo; 0.2 parts of Silwet L7622 and 0.3 parts of Silquest A187 (both from Momentive Performance Materials, Inc., OH) was dispersed in a solution of ethyl acetate/isopropyl acetate (6/4) to obtain a coating fluid of about 45% solid by weight. The resultant fluid was coated onto a 2 mil PET with a slot coating die to obtain a dried coverage of about 15.5+/−0.5 μm.

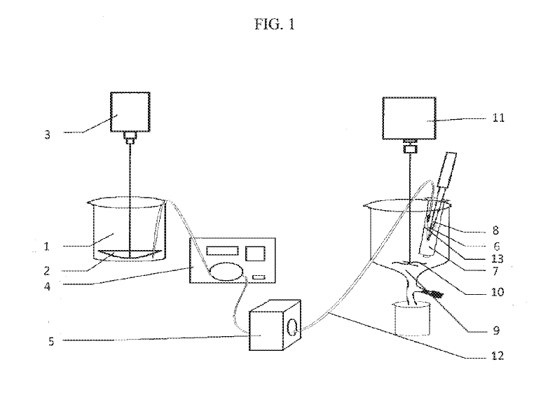

FIG. 1 illustrates and apparatus for particle encapsulation including the following: (1) a 400 mL beaker; (2) a folding dual-blade propeller; (3) a stirrer 1, overhead stirrer; (4) a digital peristaltic pump; (5) a demagnetizer; (6) a syringe needle; (7) a 30 mL syringe; (8) a sonic dismembrator; (9) 1000 mL reactor with bottom outlet; (10) a three-blade propeller; (11) a stirrer 2, Heavy-Duty Mixer; (12) tubing.

Encapsulation of Conductive Particles

One gram of metal coated conductive polymer particles (26GNR3.0-EHD from Nippon Chemical) and 49 grams of MEK (methyl ethyl ketone) were mixed in the 400 mL beaker homogeneously in a ultrasonic water bath followed by a low shear overhead stirrer at 240 rpm. To the conductive particle dispersion, 50 grams of a THF/MEK (15/85 ratio) solution containing 0.2 wt % of an insulation polymer or polymer blend were added and mixed thoroughly.

The resultant conductive particle mixture (I) was demagnetized using a demagnetizer (Magnetool Inc.) and metered continuously into a 10 mL syringe at a flow rate of 4.8 mL/min, through a 25G BD Precision Glide syringe needle having an ID of 0.01 in. The syringe needle was held closely together with a sonic probe tip (Fisher Scientific Ultrasonic Dismembrator Model 100) inside the 10 mL syringe and the conductive particle fluid within the syringe was continuously sonicated at a power of 5 watt.

As shown in FIG. 1, the syringe is partially submerged into the 1000 ml reactor containing 300 ml of isopropyl alcohol (IPA), a non-solvent of the insulation polymer to be coated onto the conductive particles. The conductive particles mixture (I) was metered into the non-solvent solution in the syringe and injected through the bottom of the 10 mL syringe into the 1000 mL reactor containing IPA continuously stirred at 280 rpm with an overhead stirrer equipped with a low shear three-blade propeller. Throughout the encapsulation process, both the tips of needle and the sonic probe were under the liquid level and held closely together. While not desiring to be bound by the theory, it is believed that the insulation polymer forms small (nano size) coacervates or swollen polymer particles upon being injected into the non-solvent bath in the syringe and adsorbed immediately onto the conductive particles nearby. The sonic probe helps reduce the size of the polymer coacervate and in turn provide better control of the thickness of the insulation polymer on the conductive particles. It also helps keep a good dispersion stability of the thus encapsulated conductive particles.

As confirmed by electron microscopy SEM (Hitachi Model S2460N), a thin, non-sticky insulation polymer layer was coated on the conductive particles which were then collected from the bottom of the reactor.

Optionally, additional non-solvent may be metered into the syringe by a separate pump (not shown) for a precise solvent/non-solvent ratio in the syringe. Alternatively, syringes having tiny holes (not shown) around the syringe wall may be used to allow the non-solvent (IPA) to flow into the syringe continuously and maintain a good control of the solvent/non-solvent ratio therein.

The insulation polymers used in Examples 1-9 are listed in Table 1 in which conductive particles as received without an insulation layer are used in a first control (Control 1) and conductive particles treated with coupling agents as taught in US Appl. 20120295098 are used in a second control (Control 2).

The microencapsulated conductive particles prepared were filled into a microcavity belt and transferred subsequently onto the adhesive as described in U.S. Patent Publication 2013/0071636 and U.S. patent application Ser. No. 13/678,935 (Multi-tier particle morphology), U.S. patent application Ser. No. 13/796,873 (Image enhancement layer) and U.S. Patent Publication 2011/0253943 continuation (low profile) to obtain various fixed array ACFs having a particle density ranging from 17,500 to 50,000 pcs/mm² with a standard deviation of less than 3%. The performance of the bonded electrodes is summarized in Table 1 and Table 2. In all cases, the adhesive thickness is controlled at 15.5+/−0.5 μm and the average coverage of encapsulation layer on the particles was controlled at about 0.1˜0.2 um.

TABLE 1
Minimum bonding space of fixed array ACFs
(Particle density = 35,000 pcs/mm²; Bonding conditions: 185° C./5 sec, 6 MPa)

| | Control | Control | Example 1 | Example 2 | Example 3 | | | | | Exam- | Exam- |
|---|---|---|---|---|---|---|---|---|---|---|---|
| | 1 | 2 | (Comparative) | (Comparative) | (Comparative) | Example 4 | Example 5 | Example 6 | Example 7 | ple 8 | ple 9 |
| Insulation | None | Silquest | PS² | PMMA³ | p(MMA- | SBS⁵ | SBS⁵/PS² | SIS⁶ | SIS⁶/PS² | SBM⁷ | M52N⁸ |
| Coating | | A187/ | | | co- | | (1:1) | | (1:1) | | |
| on | | A189¹ | | | styrene)⁴ | | | | | | |
| Conductive | | | | | | | | | | | |
| Particles | | | | | | | | | | | |
| Minimum | 13 | 5 | 3 | 7 | 4 | 9 | 3 | 6.5 | 3 | 3 | 4 |
| bonding | | | | | | | | | | | |
| space⁹ | | | | | | | | | | | |
| (um) | | | | | | | | | | | |

¹Surface treated with Silquest A-187/A-189 (1/1 ratio), both from Momentive Performance Materials, Inc., OH, as taught in US Appl. 20120295098.
²Mw = 280,000 from Aldrich.
³Mw = 120,000, from Aldrich.
⁴Mw = 100,000-150,000, MMA/styrene = 3/2 mole ratio, from Aldrich
⁵Styrene-butadiene-styrene thermoplastic elastomer from Aldrich, 30% styrene content.
⁶Styrene-isoprene-styrene thermoplastic elastomer from Scientific Polymer Products Inc., Styrene content = 14%, Mw = 150,000.
⁷Poly(styrene-b-butadiene-b-MMA) from Arkema (Nanostrength E41).
⁸Poly (MMA-b-butyl acrylate-b-MMA) from Arkema
⁹Minimum bonding space is the achieveable minimum space between the upper and lower bonding electrodes without causing short.

TABLE 2
Effect of insulation coating on fixed array ACFs
(Particle density = 17,500 pcs/mm²; Bonding conditions: 160° C./10 sec, 1 MPa;
patterned FPC bonded to non-patterned ITO glass)

| | | | | | Example 1 | Example 3 | | | | |
|---|---|---|---|---|---|---|---|---|---|---|
| | | | Control 1 | Control 2 | (Comparative) | (comparative) | Example 5 | Example 7 | Example 8 | Example 9 |
| Insulation Coating on Conductive | | | None | Silquest | PS² | p(MMA- | SBS⁵/PS² | SIS⁶/PS² | SBM⁷ | M52N⁸ |
| Particles | | | | A187/ | | co- | (1:1) | (1:1) | | |
| | | | | A189¹ | | styrene)⁴ | | | | |
| Adhesion | Peel | fresh | 1.91 | 1.91 | 1.47 | 1.71 | 1.82 | 1.99 | 2.07 | 1.81 |
| property | force¹⁰ | Thermal | 1.43 | 1.44 | 1.4 | 1.42 | 1.63 | 1.71 | 1.73 | 1.39 |
| | (kgf/in) | Shock¹² | | | | | | | | |
| | | HHHT¹³ | 1.08 | 0.91 | 0.88 | 1.06 | 1.03 | 1.13 | 1.38 | 1.07 |
| | Peel | fresh | 2.04 | 2.05 | 1.88 | 2.29 | 2.12 | 2.37 | 2.69 | 2.62 |
| | energy | Thermal | 2.47 | 2.3 | 2.3 | 2.34 | 2.51 | 2.53 | 2.67 | 2.61 |
| | (kgf- | Shock¹² | | | | | | | | |
| | mm/in) | HHHT¹³ | 1.52 | 1.51 | 1.26 | 1.59 | 1.55 | 1.62 | 1.63 | 1.53 |
| Electric | CR¹¹ | fresh | 1.84 | 1.77 | 1.86 | 1.81 | 1.82 | 1.79 | 1.76 | 1.80 |
| property | (Ohm/electrode), | Thermal | 2.17 | 2.1 | 1.98 | 1.85 | 1.98 | 1.95 | 1.85 | 2.09 |
| | | Shock¹² | | | | | | | | |
| | | HHHT¹³ | 1.96 | 1.98 | 1.93 | 1.83 | 1.92 | 1.83 | 1.81 | 1.91 |

| | | | | | | | | |
|---|---|---|---|---|---|---|---|---|
| Observed Micro-void¹⁴ rating | 7 | 6 | 5 | 8 | 9 | 8 | 10 | 10 |
| (10 is the best) | | | | | | | | |

¹⁰Sample width: 1″, Peeling speed: 20 mm/min at 90° angle. Peeling energy is the total area of the stress-strain curve and peeling force is the maximum peeling strength measured.
¹¹Contact resistance of the bonded electrodes.
¹²Measured after 7 days of thermal cycle (100° C., 30 minutes and −40° C., 30 minutes)
¹³Measured after 7 days in 85° C. and 85% RH
¹⁴The ratings are based on the number of small voids observed with ranking 10 being the best (no observable micrvoid).

As a further comparison, encapsulations of conductive particles were conducted using three phenoxy resins, PKFE, PKHB and PKCP from InChem Phenoxy Resin (Examples 10, 11 and 12, not shown in the Tables) which are fully compatible with the epoxy adhesive composition used in the ACF. PKFE in fact is used as the binder in the adhesive. All the three Examples appeared to exhibit a narrower process window for the encapsulation efficiency, the fluidic particle distribution process and the subsequent particle transfer process than those of Examples 1-9. Fixed array ACF of high particle density (e.g., greater than about 15,000 pcs/mm²) and uniformity was more difficult to achieve with insulated particles using an insulation layer of high compatibility with the epoxy adhesive composition.

The minimum bonding space, the achieve-able minimum space between the upper and lower bonding electrodes without causing short, is one of the critical characteristics of an ACF. A lower minimum bonding space represents a wider bonding process window or a higher achieve-able resolution.

It can be seen clearly from Table 1 that the minimum bonding space of the fixed array ACFs (Control 1) was reduced significantly (e.g., from 13 um to 3-9 um) by using conductive particles treated with coupling agent treatment (Control 2) as taught in US Appl. 20120295098 or an insulation polymer (Exampes 1-9). In all cases, acceptable contact resistance in the connected electrodes (Table 2) even after thermal shock and HHHT aging tests was also observed. Also, all the coated particles in Examples 1-9 showed desirable dispersion stability and handle-ability for the microfluidic distribution process as described previously.

It's also found that particles coated with insulation polymers of higher compatibility with the epoxy resin (Examples 2 and 3) resulted in poorer resolution or a higher minimum bonding space. Not to be bound by theory, it's believed that the insulation layer of high compatibility with the adhesive or of low deformation temperature tends to be plasticized or depleted by the adhesive composition and result in an insufficient protection of conductive particles. The solubility parameters of the key ingredients in the epoxy adhesive are about 10.68, 10.4 and 10.9 (Cal/cc)^{1/2} for the binder (PKFE) and the di-epoxides (bisphenol A diglycidyl ether and bisphenol F diglycidy ether), respectively (Table 3).

TABLE 3
Solubility Parameters

| | Solubility Parameter |
|---|---|
| | (δ), (Cal/cc)^{1/2} |
| Bisphenol F diglycidy ether | 10.9 |
| Bisphenol A diglycidy ether | 10.4 |
| PKHB, PKFE | 10.68 |
| PMMA | 9.25 |
| Polystyrene | 9.12 |
| Polybutyl acrylate | 9.04 |
| Polybutadiene | 8.38 |
| polyisoprene | 7.9 |
| isoprene, natural rubber | 7.4 |

A polymer having a solubility parameter in the range of 10.4+/−1.2 (Cal/cc)^{1/2} tends to be more compatible with the epoxy adhesive and less desirable. Polymers having functional groups such as carbonyl, ether, hydroxy, thiol, sulfide, amino, amide, imide, urethane, urea . . . etc that are capable of forming hydrogen bonding with the epoxide or hydroxy group of the adhesive tend to improve compatibility and be less desirable insulative coatings. As a result, PMMA and their copolymers (Examples 2, 3 and 9) tend to result in a relatively larger minimum bonding space (e.g., about 4 to 7 um) than polystyrene (Examples 1, minimum bonding space=3 um). An extensive list of solubility parameter can be found in “Polymer Handbook” by J. Brandrup, E. H. Immergut and E. A. Grulke (Wiley-Interscience) and “Prediction of Polymer Properties” by J. Bicerano (Marcel Dekker).

Although polybutadiene and polyisoprene are less compatible with the epoxy adhesives as judged from their solubility parameters, their low Tgs (about −40 to −70° C.) tend to result in a poor barrier property against the adhesive ingredients at the ACF storage conditions. The minimum bonding space of ACF having particles coated with block copolymers of high amounts of rubbery blocks (Example 4 and 6) was decreased with addition of a high molecular weight polystyrene (the same as the hard block of the block copolymer) to the insulation layer (Examples 5 and 7), probably because of the improvement of the barrier property of the insulation layer at the ACF storage conditions (typically at −10° C. to 25° C.). The improvement of the barrier properties of the insulation coating may also be achieved by addition of other polymers that are compatible with one of the blocks, particularly the incompatible block of the block copolymer. Alternatively, it may also be achieved by using of a block copolymer having a higher weight fraction of a hard block that is incompatible with the ACF adhesive resin.

The ACFs using particles protected with block copolymers and their blends are listed in Examples 4-9. Particularly useful are those block copolymers comprising a soft block or segment having a Tg or Tm lower than room temperature, preferably lower than 0° C., and a hard block/segment having a Tg or Tm higher than room temperature, preferably higher than the coating or particle transfer process temperature (typically 50-90° C.). In Examples 4-9, the Tgs of the soft blocks (polybutadiene, polyisoprene and polybutyl acrylate) used are below room temperature and the Tgs of the hard blocks (polystyrene and PMMA) are about 100° C. The hard and soft blocks typically form a two phase morphology after the block copolymer is processed by, for example, drying, coating and casting, etc.

As shown in Table 1, ACF samples with block copolymer coated particles exhibited a significantly lower minimum bonding space. It's also evident from Table 2 that ACFs using particles protected with block copolymers or their blends (Examples 5, 7-9) exhibited superior performance in total peeling energy, maximum peeling force and observable microvoid ranking of the bonded electrodes even after accelerated aging and thermal shock tests than those with the coupling agent only (Control 2) and thermoplastic polymers (Examples 1, 3). Not to be bound by theory, it is believed that the elastomeric characteristic of the block copolymer used in Examples 5, 7, 8 and 9 exhibited desirable properties as impact/shock modifiers to improve adhesion strength or as low profile additive to reduce shrinkage or warpage of the cured adhesive.

The MMA-BA-MMA block copolymer (Example 9) showed a higher minimum bonding space than the styrene-butadiene-MMA bock copolymer (Example 8), probably due to its higher concentration of the PMMA block which is more compatible with the ACF adhesive than the polystyrene or polybutadiene block.

Not to be bound by theory, it is believed that the block copolymers comprising a block that is incompatible with the ACF adhesive resin exhibit a higher adsorption efficiency on the conductive particles and resulted in a significant reduction in the probability of the insulation layer being desorbed or released from the particles in the non-electrode area (the gap). As a result, the probability of short circuit in the X-Y plane and the minimum bonding space are significantly reduced. The block copolymer in the connected electrode area, are more easily removed during the bonding process than a conventional thermoset or gel insulation layer to expose the conductive shell of the particles to provide a connection of high conductivity. The thus removed block copolymer in the electrode area also functions as an impact modifier or a low profile additive to reduce the shrinkage of curing and result in a significant increase in adhesion strength as well as a reduction in microvoid formation which is known to be detrimental to the environmental stability of the connected device.

According to above descriptions, drawings and examples, this invention discloses an anisotropic conductive film (ACF) that includes a plurality of electrically conductive particles surface treated with an insulating layer comprising a block copolymer comprising a block or segment that is incompatible with the ACF adhesive. In one embodiment, the incompatible block or segment of the block copolymer has a difference in solubility parameter of at least 1.2 (Cal/cc)^{1/2} from that of the ACF adhesive resin. Insulated conductive particles are disposed in predefined non-random particle locations as a non-random array in or on an adhesive layer wherein the non-random particle locations corresponding to a plurality of predefined microcavity locations of an array of microcavities for carrying and transferring the electrically conductive particles to the adhesive layer. The conductive particles are transferred to an adhesive layer.

In addition to the above embodiment, this invention further discloses an electronic device with electronic components connected with an ACF of this invention wherein the ACF has non-random surface treated conductive particle array arranged according to the processing methods described above. In a particular embodiment, the electronic device comprises a display device. In another embodiment, the electronic device comprises a semiconductor chip. In another embodiment, the electronic device comprises a printed circuit board with printed wire. In another preferred embodiment, the electronic device comprises a flexible printed circuit board with printed wire.

Having described the invention in detail and by reference to specific embodiments thereof, it will be apparent that numerous variations and modifications are possible without departing from the scope of the invention as defined by the following claims.

What is claimed is:

1. An anisotropic conductive film (ACF) comprising: (a) an adhesive layer having a substantially uniform thickness; and (b) a plurality of conductive particles individually adhered to the adhesive layer, wherein the conductive particles are coated with an insulation layer comprising a block copolymer comprising a block or segment that is incompatible with the adhesive resin of the adhesive layer of the ACF and the plurality of conductive particles are arranged in a non-random array having an X and Y direction.

2. The ACF of claim 1 wherein the block copolymer includes a hard and a soft block or segment.

3. The ACF of claim 1 wherein the soft block or segment has a Tg or Tm lower than about 25° C.

4. The ACF of claim 1 wherein the hard block or segment has a Tg or Tm higher than about 50° C.,

5. The ACF of claim 1 wherein said incompatible block or segment of the block copolymer has a difference in solubility parameter of at least about 1.2 (Cal/cc)^{1/2} as compared to that of the ACF adhesive resin.

6. The ACF of claim 1 wherein said insulation layer comprises a blend of a block copolymer and a thermoplastic polymer (TPP) that is incompatible with the ACF adhesive resin.

7. The ACF of claim 3 wherein said thermoplastic polymer is the same as or compatible with one of the blocks or segments of the block copolymer.

8. The ACF of claim 6 wherein the TPP has a difference in solubility parameter of at least about 1.2 (Cal/cc)^{1/2} as compared to that of the ACF resin.

9. The ACF of claim 1 wherein said block copolymer includes a block or segment selected from a group consisting of styrenic, olefinic, polyamide, polyurethane, polyester, polyacrylate and polymethacrylate blocks.

10. The ACF of claim 9 wherein the block copolymer includes at least about 10% by weight of a styrenic block.

11. The ACF of claim 1 wherein at least a portion of the conductive particles are partially embedded in the adhesive layer.

12. The ACF of claim 1 wherein the block copolymer is present on the surface of the conductive particle in an amount of about 5 to 100% surface coverage.

13. The ACF of claim 1 wherein the block copolymer is present on the surface of the conductive particle in an amount of about 20% to 100% of surface coverage.

14. The ACF of claim 1 wherein the particles are arranged in an array having a pitch of about 3 to 30 μm in the X and/or Y direction.

15. The ACF of claim 1 wherein the particle sites are arranged in an array having a pitch of about 5 to 12 μm in the X and/or Y direction.

16. The ACF of claim 15 wherein a substantial proportion of the particle sites have no more than one conductive particle at each particle site.

17. The ACF of claim 1 wherein the conductive particle includes a layer of a metal, an intermetallic compound, or an interpenetrating metal compound.

18. The ACF of claim 1 wherein the block copolymer is a styrenic or acrylic block copolymer.

19. The ACF of claim 18 wherein the block copolymer is selected from a group consisting of poly(styrene-b-butadiene-b-styrene), poly(styrene-b-isoprene-b-styrene), poly(styrene-b-butadiene-b-MMA), poly(MMA-b-butyl acrylate-b-MMA) and mixtures thereof.

20. The ACF of claim 1 wherein the insulation layer is a blend of a block copolymer with a TPP selected from the group consisting of polystyrene, poly(a-methylstyrene), poly(methacrylate), poly(acrylate) or mixtures or copolymers thereof.

21. The ACF of claim 11 wherein less than about three-fourths of the particle diameter is embedded in the adhesive layer.

22. The ACF of claim 1 wherein the adhesive includes an epoxy resin, phenoxy resin, acrylic resin or cyanate ester resin.

23. The ACF of claim 1 wherein the adhesive includes a multifunctional epoxide, multifunctional acrylate, multifunctional methacrylate, or multifunctional cyanate ester.

24. The ACF of claim 21 wherein less than about two-thirds of the particle diameter is embedded in the adhesive layer.

25. The ACF of claim 24 wherein about one-half to two-thirds of the particle diameter is embedded in the adhesive layer.

26. The ACF of claim 1 wherein an electronic device contacts the conductive particles on the surface of the adhesive layer.

27. The ACF of claim 1 wherein the electronic device is an integrated circuit, a printed circuit, a light emitting diode, or a display device.

28. The ACF of claim 1 wherein the adhesive layer is about 5 to 35 μm thick.

29. The ACF of claim 1 wherein the adhesive layer is about 10 to 25 μm thick.

30-47. (canceled)
